(19) United States
(12) Patent Application Publication
(10) Pub. No.: US 2018/0290577 A1
(43) Pub. Date: Oct. 11, 2018

(54) METHOD FOR OPERATING A MASSAGE DEVICE OF A SEAT

(71) Applicant: Brose Fahrzeugteile GmbH & Co. Kommanditgesellschaft, Bamberg, Bamberg (DE)

(72) Inventor: Alexander MUELLER, Bischberg (DE)

(73) Assignee: Brose Fahrzeugteile GmbH & Co. Kommanditgesellscha ft, Bamberg, Bamberg (DE)

(21) Appl. No.: 15/947,355

(22) Filed: Apr. 6, 2018

(30) Foreign Application Priority Data
Apr. 6, 2017 (DE) 10 2017 205 934.6

(51) Int. Cl. B60N 2/90; B60N 2/00; H03K 17/955

(52) U.S. Cl. CPC B60N 2/976; B60R 21/01532; H03K 17/955; B60N 2/002

(57) ABSTRACT

A method for operating a massage device of a seat, in particular of a motor vehicle, having a massage drive with an unbalance which is driven by means of an electric motor, and an electrical line for operating the massage drive. By means of a component of the massage device, a change in capacitance due to a change in occupancy of at least one section of the seat is detected, and based on the change in capacitance, the energization of the electric motor is adjusted. A massage device of a seat and a vehicle seat of a motor vehicle as well as a component of a massage device of a seat are also provided.

This nonprovisional application claims priority under 35 U.S.C. § 119(a) to German Patent Application No. 10 2017 205 934.6, which was filed in Germany on Apr. 6, 2017, and which is herein incorporated by reference.

### BACKGROUND OF THE INVENTION

### Field of the Invention

The present invention relates to a method for operating a massage device of a seat as well as to a massage device of the seat as well as to the use of a component of a massage device of a seat. The seat is preferably a component of a motor vehicle. The invention further relates to a vehicle seat of a motor vehicle.

Motor vehicles comprise a number of accessories, which do not directly serve the propulsion of the motor vehicle. In most cases, the comfort for the user of the motor vehicle is increased by means of these accessories. One such accessory is a massage device that is part of a vehicle seat. When this is activated, a certain area of the vehicle seat is moved intermittently, such as a backrest or a part of a backrest. As a result, the blood circulation of the user of the vehicle seat is stimulated, making the use of the vehicle more comfortable. Also, with this motor vehicle, drives of a comparatively long duration can be carried out without tiring the user.

### Description of the Background Art

Motor vehicle seats also usually have seat occupancy detection. As a function of the seat occupancy detection, for example, the correct application of a seat belt is monitored and, optionally, a warning sound is emitted. In addition, in order to save costs, airbags are usually only activated in a crash if the seat is occupied. In order to detect whether the seat is occupied, a weight sensor is usually used or the deformation of the seat due to occupancy by a person is detected. In one alternative, a capacitive sensor electrode is used, by means of which an electromagnetic field is created and monitored in the region of the seat. A change in a dielectric constant is in this case detected on the basis of a change in capacitance. The change in the dielectric constant hereby stems from the presence of a person in the seat area. If a change in capacitance is detected, the seat occupancy is also recognized.

### SUMMARY OF THE INVENTION

It is therefore an object of the present invention to provide a particularly suitable method for operating a massage device as well as a particularly suitable massage device of a seat as well as a particularly suitable vehicle seat of a motor vehicle and a particularly suitable use of a component of a massage device of a seat, wherein in particular production costs are reduced and service life is increased and suitably, the acoustic quality is improved.

The method can be used to operate a massage device. The massage device is a component of a seat, and characteristically, a massage function is performed by the massage device. Here, for example, a part of the seat, such as the seat surface or a backrest, is moved, in particular intermittently. The seat, and thus the massage device, is preferably a part of a motor vehicle, and the seat is, for example, a driver's seat or a passenger seat.

The massage device comprises a (first) massage drive and a (first) electrical line, wherein said electrical line serves to operate the massage drive. In this case, an electrical current or an electrical voltage is provided by means of the electrical line, for example, in a certain operating mode. In other words, the electrical line is a power line. In a further alternative, the electrical line is a data line, wherein in particular operating parameters are directed via the data line to the massage drive so that the massage drive is operated on the basis of the electrical line. For example, the massage drive is supplied with a current by means of the electrical line, wherein, for example, the corresponding parameters for energization are transmitted via the electrical line. In summary, the electrical line is in electrical contact with the massage drive.

The massage drive has an unbalance driven by an electric motor, and the electrical line is expediently used to operate the electric motor. The unbalance is driven by means of the electric motor. Due to this unbalance, the massage drive is suitably set in motion, wherein this movement is intermittent. In this case, in the assembled state, the massage drive is suitably coupled to a further part of the seat, for example, a backrest or the seat surface, so that by means of the unbalance, the respective part is moved, in particular bulged.

The method provides that by means of a component in the massage device itself, in a first step, a change in capacitance due to a change in occupancy of at least a section of the seat is detected. Below, capacitance is in particular understood to be the electrical capacitance, for example, of an electrical field and/or an electrical capacitor. Here, suitably the electrical capacitance is detected, and by means of the component of the massage device, by means of which the detection is carried out, suitably at least partially a capacitor is formed. This component preferably acts as a capacitive sensor electrode. For example, an electromagnetic field is detected or the electromagnetic field is at least partially created by means of the component. In this case, the component is provided and arranged such that only, or at least then when the section of the seat is occupied, the change in capacitance is detected. In other words, the change in capacitance is detected when a section of the seat, for example, the seat surface or a part of a seat surface, a backrest part or the entire backrest, is occupied. In summary, the section is, for example, a portion of a seat surface or of a backrest, or the seat surface or the entire backrest. Alternatively, the section is formed by means of the backrest and the seat surface of the seat.

In summary, the change in the dielectric constant is detected on the basis of the occupancy. In other words, if a person sits down on the seat, the dielectric constant is changed to be different from the dielectric constant of air. This is detected by means of the component of the massage device, which functions as a component of a capacitor. The change in capacitance is detected, for example, by calculating an absolute value and comparing it with a theoretical request. In an alternative to this, for example, in each case the capacitance is detected at certain times, in particular 1 minute, 10 seconds, 1 second or 0.5 seconds apart. Suitably, the successively detected capacitances are compared with each other and the change in capacitance is derived therefrom. In summary, in particular a change in the occupancy of at least a section of the seat is based on the change in capacitance.

In a further step, an energization of the electric motor is adjusted to the change in capacitance. Due to the adjustment of the energization, in this case a torque that is transferred to the unbalance by means of the electric motor is adjusted and/or a rotational speed of the unbalance is adjusted. Thus, in particular the energization of the electric motor is adjusted as a function of the occupancy of the seat, wherein the occupancy is itself detected by means of the component of the massage device, which is preferably used as a capacitive sensor electrode. For example, the occupancy of the section of the seat is detected, said section being moved or being able to be moved by the electric motor whose energization is configured to carry out the massage function.

Due to the adjustment of the energization as a function of the detected occupancy, the massage function is adapted to the user, which increases his or her comfort level. Moreover, no further additional component is required to detect the occupancy, which is why production costs are reduced. Further it is not necessary to provide further space, which is why a comparatively compact massage device is provided. Also, the service life of the electric motor is increased in this way. Suitably, the electric motor is not operated at maximum capacitance, if, for example, no occupancy is detected, which improves the acoustic quality. Since there is no occupancy, this is not required.

For example, the capacitance is detected following a user input. For example, the massage device is activated by means of the user input. As a function of the user input, for example, energization of the massage drive, in particular the electric motor, is initiated and thus, the unbalance is set into motion. Following this or at the same time or previous in time, but at least after detecting the user input, the capacitance is detected and adjusted depending on the capacitance of the energization of the electric motor. Here, for example, energization is increased or decreased from a fixed default value, which is given following the user input, depending on the capacitance. Since the capacitance is detected following the user input, which corresponds in particular to an activation of the massage device, the change in occupancy is detected only if the massage drive is to be activated. Thus, electromagnetic compatibility (EMC) is increased, since, in particular if an electromagnetic field is created by the component of the massage device, the emission of electromagnetic fields is reduced. After detecting the user input, the detection of the capacitance is appropriately repeated, in particular cyclically, for example 5 minutes, 1 minute, 10 seconds, 1 second, or 0.5 seconds apart. Thus, there is always information available as to whether or not the section is occupied.

In summary, the user input corresponds to an activation of the massage device. If the seat is part of the motor vehicle, in a further alternative, the user input, for example, may be the unlocking of the motor vehicle or the starting of the internal combustion engine or the placing of the electric motor of the motor vehicle into an operating state that activates the so-called accelerator pedal, resulting in a propulsion of the motor vehicle. Consequently, the occupancy of the seat is detected when the motor vehicle is in a state where it can be used, or in which can move forward. Suitably, a detected occupancy of the seat is forwarded to an on-board computer of a motor vehicle, for example, via a bus system, or at least, this information is made available by a bus system. Provided that the massage device is not part of a motor vehicle, the user input corresponds, for example, to a shifting of the massage device from the turned-off state to stand-by mode.

In particular, energization is increased if the detected capacitance corresponds to the occupancy of the section of the seat. For example, energization is set to a maximum value, which is determined in particular on the basis of structural specifications of the massage drive. Alternatively or in combination therewith, energization is initiated so that the energization is set from a value of zero (0) to a certain value. This is, for example, the maximum or another value which lies between the maximum and the previous state of no energization. Expediently, the massage drive is associated with the section of the seat of which the occupancy is detected. Suitably, energization is thus started if an occupancy is detected.

Alternatively or in combination therewith, the energization of the electric motor is preferably reduced and, for example, completely reduced and thus interrupted, as long as no occupancy is detected in the section. In an alternative to this, the electric motor is operated in a certain range and the energization is adapted thereto, in that the acoustic quality of the electric motor is improved. In particular, the transmission of acoustic signals is reduced in this operating range. Thus, the acoustic quality is improved for the user. In addition, the electric motor is then substantially operated only at a fairly high power output, as long as this is required by the occupancy. If no occupancy is detected, the electric motor is operated at reduced power, which reduces energy consumption and increases the service life of the massage drive. Here, the impression is not worsened for the user, as he or she does not perceive the massage effect of the massage drive since there is no occupancy.

For example, the capacitance between the component and ground is calculated. If the massage drive is a component of the motor vehicle, for example, the capacitance between the component and the body or an element connected with the body in an electrically conducting manner, in particular a support structure/holding structure of the seat, may be calculated. In other words, the component forms one electrode, and ground forms the second electrode of the capacitor, for which the capacitance or the change in capacitance due to the changes in occupancy of the seat section is detected. For example, by applying an electrical potential to the component, an electrical voltage is created between the component and ground. For example, an AC voltage is applied to the component. Based on a change, an occurrence of an electrical current, the capacitance is advantageously detected. Alternatively, the capacitance between the component and another part of the massage drive is detected.

Suitably, the massage device has a second massage drive, which in particular also has an unbalance which is driven by an electric motor and is preferably identical to the massage drive. The second massage drive is operated by means of a second electrical line, which is in electrical contact with the second massage drive and is preferably identical to the electrical line. In other words, the second electrical line is used to operate the second massage drive. Particularly preferably, the capacitance between the component and the second massage drive, for example, a second component of the second massage drive, is determined. The capacitance is thus determined between the component and the second component of the second massage drive and/or the second electrical line. In other words, one electrode is formed by the component of the massage drive and the second electrode by the second component of the second massage drive or the second electrical line. Thus, the capacitance is determined by means of two elements of the massage device, which are suitably arranged in a defined geometric relationship, in particular at a fixed distance or an almost fixed distance to each other. As a result, the mounting of the massage drive to the seat can be done comparatively freely, and various types of seats can be used without the specific mounting position having a very large impact on the capacitance that is detected. Thus, the capacitance is determined essentially only using the occupancy of the section of the seat.

For example, a housing of the massage drive is used as a component. The housing is expediently made of a metal, for example a sheet metal. At a minimum, however, the housing is made of an electrically conductive material. In particular, the housing of the electric motor is used as the component. Suitably, in this case the capacitance is detected when the massage drive is not energized. For this purpose, an electrical potential is suitably applied to the housing. As long as energization of the drive occurs, the housing is suitably electrically connected to ground, so that a transmission of unwanted electromagnetic waves due to the electric motor is substantially prevented. This way, with a non-driven unbalance, the housing is used as the capacitive sensor electrode. As a result, a pre-existing and electrically contacted component is used as the capacitive sensor electrode, which further reduces costs.

Alternatively, the electrical line is used as a component, wherein the electrical line is, for example, a power line or a data line and is designed in particular single-core or multi-core. The electrical line can be installed relatively freely within other components of the seat, such as a seat cushion or a backrest. Consequently, the area monitored by means of the electrical line can be determined comparatively freely, so that the section can be selected substantially freely. In this way, flexibility is increased and no further component is necessary because the line is already used for the operation of the massage drive and thus fulfills two functions, which reduces manufacturing costs.

The massage device is a component of a seat and, for example, a component of a motor vehicle. In particular, in this case the massage device is part of a driver's seat or a passenger seat. The massage device comprises a massage drive, which includes an unbalance which is driven by an electric motor. Furthermore, the massage device has an electrical line for operating the massage drive. For this purpose, the electrical line is suitably in electrical contact with the massage drive, advantageously, with the electric motor. The massage drive and/or the electrical line are assigned to a (first) section. In other words, the massage drive and the electrical line are assigned to, or at least can be assigned to, a particular spatial area so that the spatial position of the massage device or the electrical wire is determined. In the assembled state, the section is suitably a part of the seat, and the massage drive or the electrical line can be assigned to said part of the seat. For example, the section is a portion of a seat surface or a back of the seat. Alternatively, the section is the entire seat surface or the entire backrest or a combination of seat and backrest.

The massage device is operated according to a method in which by means of a component of the massage device, a change in capacitance is detected when the occupancy of the section of the seat is changed. On the basis of the change in capacitance, the energization of the electric motor is adjusted. Thus, the massage drive and the electrical line are assigned to the section in such a way that the change in capacitance is detected due to a change in the occupancy of the section of the seat. Advantageously, during operation of the electric motor, a section or at least a portion of the section is moved by means of the electric motor or the unbalance.

The massage device expediently includes a control unit/control device, which is suitable, preferably provided and configured, for performing the method. The control device is, for example, a central control device (control unit) of the massage device or part of the massage drive, and is suitably attached to the electric motor. For example, in this case, the control unit additionally serves to adjust the energization of the electric motor. Preferably, the massage device further comprises a central control unit by means of which, for example, communication with further components, for example, an input device and/or a bus system can take place, in particular if the massage device is part of the motor vehicle.

The massage device comprises, for example, a third massage drive and/or a third electrical line, which are assigned to a second section. Suitably, the third electrical line serves to operate the third massage drive. The second section is not congruent with the (first) section and, for example, is spaced apart therefrom or is adjacent thereto. Suitably, the massage device is operated such that a change in a second capacitance due to a change in occupancy of the second section is detected by means of the third massage drive and/or the third electrical line. Based on the change in the second capacitance, in particular the energization of the third massage drive is adjusted. The third massage drive also suitably comprises an electric motor and an unbalance, and preferably is identical to the (first) massage drive. The third electrical line is preferably identical to the (first) electrical line. By way of example, the third massage drive or the third electrical line is used as the second massage drive or as the second electrical line, and the capacitance is determined between the third massage drive or the third electrical line and the component of the massage drive. Preferably, the third massage drive also comprises a control device, in particular if the massage drive comprises one. As a consequence, it is essentially decentrally recorded, whether the respectively assigned section is occupied, wherein suitably a central control unit provides general activation.

The massage device suitably can be formed only of the massage drive and the electrical line or the massage drives and the electrical lines. For example, the massage device may be include the massage drives, the electrical lines and an optional control unit. However, at a minium the massage device in particular does not have a separate capacitive sensor electrode or any other sensors by means of which the occupancy of the seat can be detected, i.e., which are in particular provided and configured simply to detect the occupancy of the section of the seat.

The vehicle seat is a component of a motor vehicle and comprises a massage device. The vehicle seat expediently is a driver's seat, i.e., the seat which is occupied by the operator of the motor vehicle. In particular, the driver's seat comprises a seat surface and suitably, a backrest. The seat surface and/or the backrest advantageously comprise a molded part of cold (polyurethane) foam, which is provided with a coating, such as fabric or leather. In addition, the vehicle seat comprises a massage device having a massage drive, which comprises an unbalance driven by an electric motor, and which is assigned to an electrical line for operating the massage drive, wherein the massage drive and/or the electrical line are assigned to a section of the seat. The massage drive is expediently arranged in a recess within the molded part made of cold foam, and during operation of the unbalance, the coating, i.e., in particular the fabric or the leather, is suitably bulged, in particular intermittently. The massage drive is operated according to a method, in which a change in capacitance due to a change in occupancy of the section of the seat is detected by means of a component of the massage device, and in which based on the change in capacitance, the energization of the electric motor is adjusted.

A component of a massage device of a seat, having a massage drive comprising an unbalance driven by an electric motor and an electrical line for operating the massage drive, is used as a capacitive sensor electrode for detecting the occupancy of at least a section of the seat. The seat and thus the massage device are preferably a part of a motor vehicle, and the electrical line is suitably in electrical contact with the massage drive. In summary, a component of the massage device thus fulfills a dual function, namely, for a start, the occupancy of the section of the seat, as well as another function which serves to carry out a massage function. As a result, the number of required components and thus manufacturing costs are reduced.

If a component is referred to as a first, second, third, . . . component, it is to be understood in particular as only a specific component. In particular, this does not mean that a certain number of such components is present. In particular, it does not imply that a second massage drive is provided if the third massage drive is provided.

The developments and advantages described in connection with the massage device are to be applied analogously to the vehicle seat/the use and vice versa.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematically simplified view of a motor vehicle with a vehicle seat comprising a massage device,

FIG. 2 is a perspective view of the massage device with several massage drives,

FIG. 3 is a schematic view of one of the massage drives,

FIG. 4 is a perspective view of the vehicle seat with the massage device,

FIG. 5 is a method of operating the massage device, and

FIGS. 6 and 7 illustrate different operating modes of the massage device.

### DETAILED DESCRIPTION

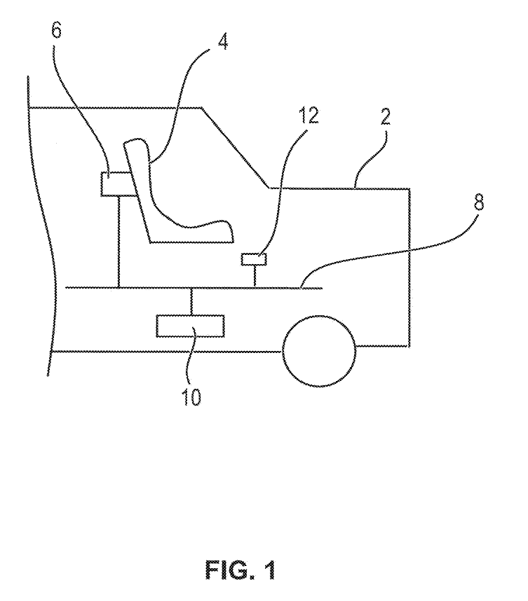

FIG. 1 shows a simplified schematic of a motor vehicle 2 with a vehicle seat 4. The vehicle seat 4 comprises a massage device 6, which is signal-connected with another BUS system 8. The further BUS system 8 is based on the CAN standard, and an onboard computer 10 as well as a further BUS devices 12 are each a part of the other BUS system 8. By means of the onboard computer 10, requests are transferred to the massage device 6 and the other BUS devices 12. Also, an exchange of operational data takes place via the other BUS system 8.

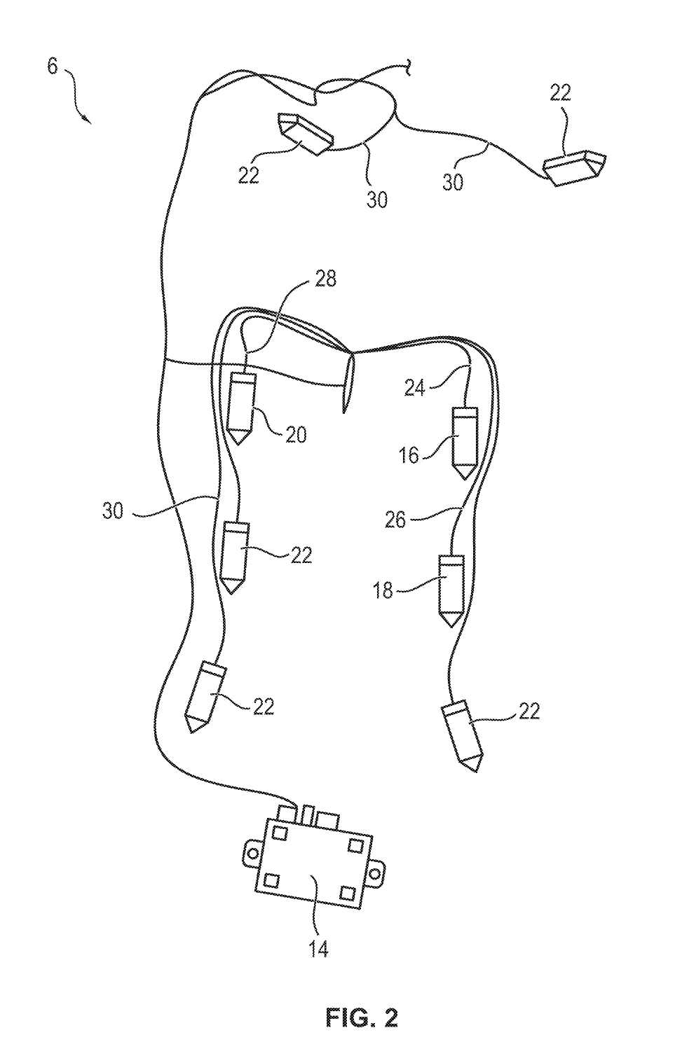

FIG. 2 shows the massage device 6, which has a control unit 14 and a first massage drive 16, a second massage drive 18, a third massage drive 20 and five other massage drives 22. The first massage drive 16 is electrically and signal-technically coupled with the control unit 14 by means of a first electrical line 24, and the second massage drive 18 is electrically and signal-technically coupled with the control unit 14 by means of a second electrical line 26. The third massage drive 20 is signal-technically and electrically coupled with the control unit 14 by means of a third electrical line, and the further massage drives 22 respectively signal-technically and electrically coupled by means of a further electrical line 30. Here, the electrical lines 24, 26, 28, 30 each serve for operating the respectively assigned massage drive 14, 18, 20, 22. The massage device 6 is composed of the massage drives 16, 18, 20, 22, the electrical lines 24, 26, 28, 30 and the control unit 14.

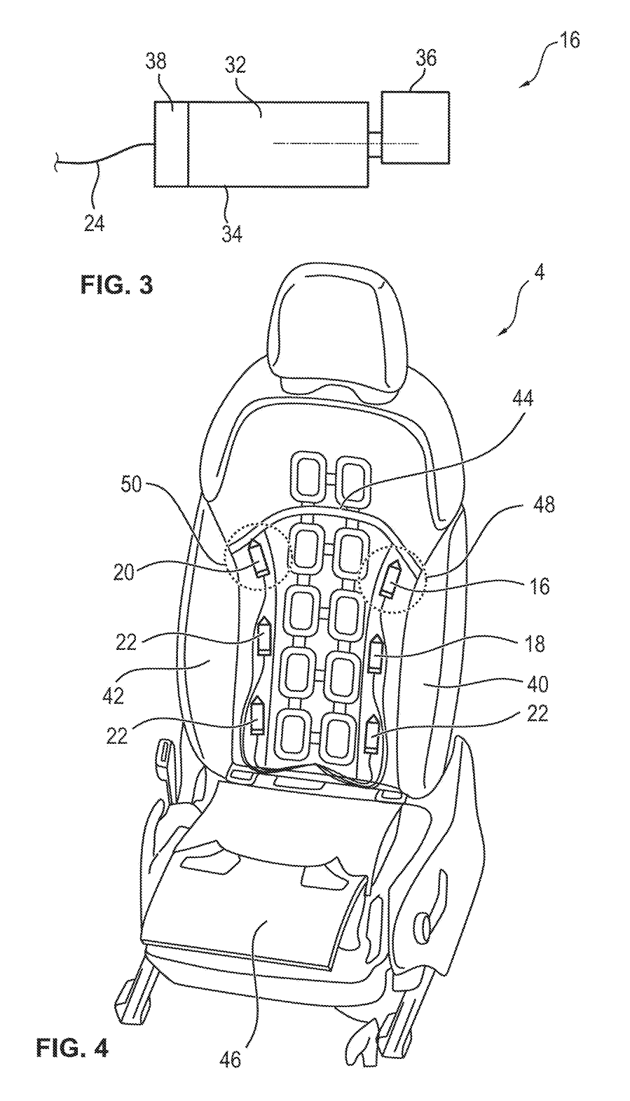

FIG. 3 illustrates the first massage drive 16, which is identical to the second massage drive 18, to the third massage drive 20 and to the other massage drives 22. The first massage drive 16 has an electric motor 32 with a housing 34 made of a metal sheet. An unbalance 36 is connected to an unillustrated shaft of the electric motor 32, which is accordingly driven by the electric motor 32. In a rotational movement of the electric motor 32 and thus a rotational movement of the unbalance 36, the first massage drive 16 is set into rhythmic motion. Further, the first massage drive 16 includes a control device 38, by means of which the electric motor 32 is energized. The control device 38 is in electrical contact with the first electrical line 24, and during operation, data is exchanged between the control unit 14 and the control device 38 via the first electrical line, wherein via another wire of the electrical line 24, an electrical current is supplied to the control device 38.

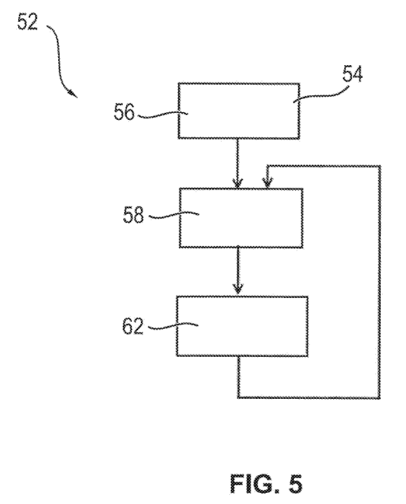

FIG. 4 shows the driver's seat 4 in a perspective view but without a seat cover. The (driver) seat 4 comprises a backrest 40, which comprises a molded part 42 made of a cold foam, in which a metal holding structure 44 is embedded for purposes of stabilization. The control unit 14 is connected to the underside of a seat surface 46 of the seat 4. The molded part 42 has a number of recesses, wherein within each one of these, the first massage drive 16, the second massage drive 18, the third massage drive 20 and the further massage drives 22 as well as the electrical lines 24, 26, 28, 30 are disposed. The massage drives 16, 18, 20, 22 are spaced apart from each other, and the first massage drive 16 is assigned to a section 48 and the third massage drive 20 is assigned to a second section 50. The sections 48, 50 correspond in this case to the portions of the seat 4 which are bulged during operation of the respective assigned massage drive 16, 20 due to the respective unbalance 36. Each of the other massage drives 22 and the second massage drive 18 are assigned a section of the seat 4 not shown in detail. The respective electrical lines 24, 26, 28, 30 which serve for operating the assigned massage drive 16, 18, 20, 22 are in this case at least partially assigned to the respective section.

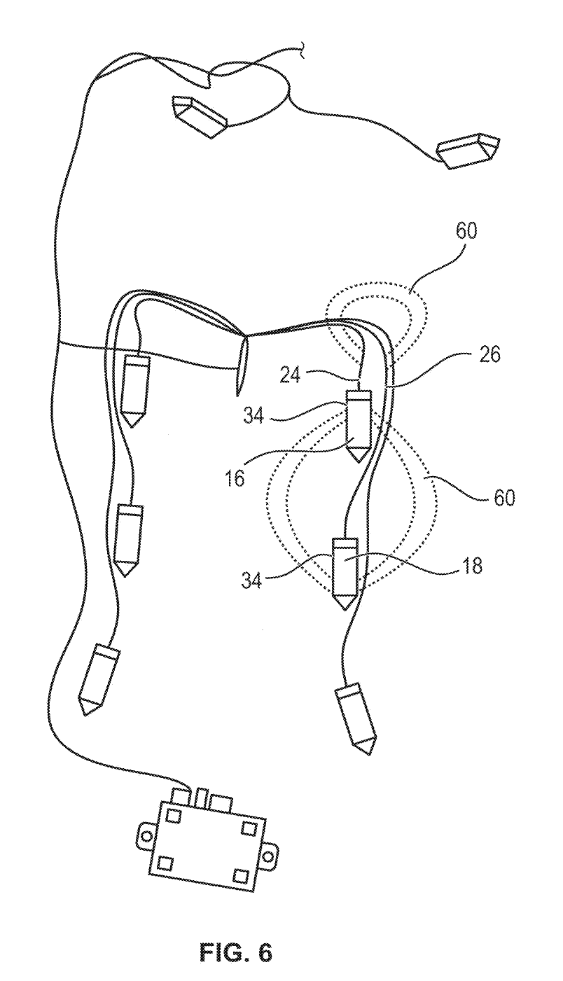

FIG. 5 shows a method 52 for operating the massage device 6, which is performed at least partially by means of the control device 14 and the respective control devices 38 of the massage drives 14, 18, 20, 22. In a first step 54, a user input 56 is detected, which is passed to the control unit 14 via the bus system 8. The user input 56 corresponds to a request of the user of the seat 4 to perform a massage function.

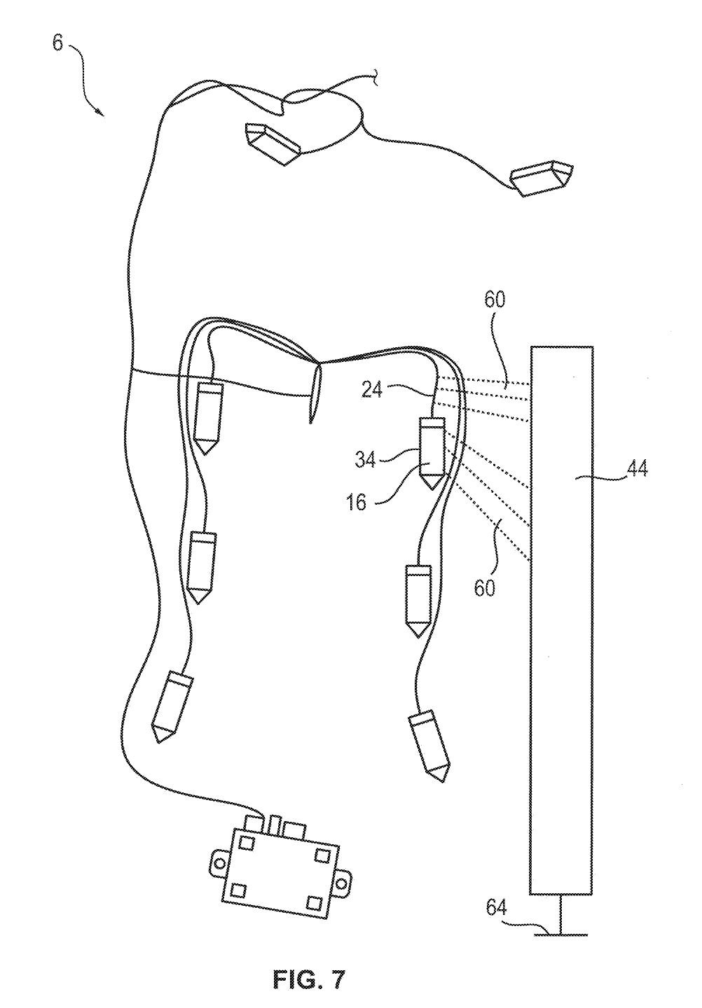

In a second step 58, a change in capacitance due to a change in occupancy of at least the section 48 of the seat 4 is detected. For this purpose, in one embodiment which is shown in FIG. 6, an electromagnetic field 60 is created by means of the housing 34 of the electric motor 32 of the first massage drive 16 as well as by means of the housing 34 of the second massage drive 18. The parameters of the electromagnetic/electrical field 60 are compared to values stored in the control unit 14 and the control devices 38 which do not correspond to any occupancy, that is to say if the user does not occupy the section 48 and is thus spaced therefrom. In other words, an electromagnetic field 60 is formed between the first massage drive 16 and the second massage drive 18, and the housings 34 of the two massage drives 16, 18 act as electrodes of a capacitor which is formed by means of the housings 34. For this purpose, the housings 34 are set to a certain electrical potential, which is, for example, constant or oscillates over time. As a function of the determined, occurring capacitance, which functions as a parameter of the electromagnetic field 60, a conclusion is thus possible as to whether the electromagnetic field 60 only substantially propagates in the air or near the body of the user of the seat 4. If the calculated dielectric constant corresponds to the user of the seat 4 and thus in particular deviates from the dielectric constant containing air, occupancy is recognized.

In a further embodiment, the electrical field 60 is created between the first line 24 and the second line 26. Thus, the capacitor is provided by the two electrical lines 24, 26. In summary, by means of a component of the massage device 6, the change in capacitance due to a change in occupancy of the section 48 of the seat 4 is detected, wherein either the housing 34 of the electric motor 32 of the first massage drive 16 or the first electrical line 24 are used as a component. In an alternative, the electromagnetic field 60 is created between one of the lines 24, 26 of one of the massage drives 16, 18 and between a further electrical line 24, 26. In summary, the capacitance between the housing 34 of the first massage drive 16 or the first electrical line 24 and the housing 34 of the second massage drive 18 and/or the second electrical line 26 is calculated.

In a subsequent third step 62, the energization of the electric motor 32 of the first massage drive 16 is adjusted on the basis of the change in capacitance. In this case, energization is increased if the second work step 58 has ascertained that section 48 is occupied. If no occupancy of section 48 was detected, i.e., if the user is not touching section 48, the energization of the electric motor 32 of the first massage drive 16 is omitted or the electric motor 32 is operated in a certain range in which the emission of acoustic signals is reduced. In a further alternative of the invention, directly after detecting the user input 56, the energization of the electric motor 32 is initiated, and subsequently thereto, initially the second step 58 is performed. Depending on the subsequently detected capacitance, the energization is adjusted, which is created directly following the first step 54. Alternatively, first, before the electric motor 32 is energized, the capacitance is detected and only when the occupancy is detected is the electric motor 32 set into rotation.

Furthermore, the third massage drive 20 and/or the third electrical line 28 detects whether or not the second section 50 is occupied. If the second section 50 is occupied, this massage drive 20 is also energized and thus, the unbalance 36 of the third massage drive 20 is set in motion. If the second section 50 is not occupied, the electic motor 32 is not energized, or the electric motor 32 is operated within a predefined speed range. Also, by means of the second massage drive 18 and the further massage drives 22, the occupancy of the respectively assigned section is detected and as a function thereof, the respective electric motor 32 is energized.

FIG. 7 shows a modification of the massage device 6. In this case, the electromagnetic field 60 is created between the housing 34 of the first massage drive 16 or the first electrical line 24 and the holding structure 44 which is electrically connected to ground 64. In this case, ground 64 is provided by means of the body of the motor vehicle 2 and the holding structure 44 is in electrical contact with the motor vehicle body. Accordingly, the capacitance between the first massage drive 16 or the first electrical line 24 and ground 64 is calculated. Also, in each case an electrical field 60 is created between ground 64 and the second massage drive 18, the third massage drive 20, the further massage drives 22 or the second electrical line 26, the third electrical line 28 or the further electrical lines 30 and ground 64, wherein this is done, for example, successively. The evaluation of the capacitance expediently occurs by means of the control device 38 of the respective massage drive 16, 18, 20, 22.

In summary, the electric motors 32 or the electrical lines 24, 26, 28, 30 and optionally the support structure 44 are used as capacitive sensor electrodes for seat occupancy detection. This is done, for example, qualitatively or quantitatively. As long as it is recognized that the respective section 48, 50 is not occupied, i.e., if the person's back is not touching the backrest 40, the vibration in this section 48, 50 is set, resulting in protection of the electro motors 32. The measuring principle here is either a one- or two-electrode principle. In yet other words, each of the massage drives 16, 18, 20, 22 has a metallic housing 34, which is installed in the cold foam of the molded part 42. These housings 34 are used as electrodes in order to establish the electromagnetic field 60, which in particular is a capacitive field. The electromagnetic field 60 is in this case evaluated by means of the control device 38, and the electromagnetic field is created between two or more components 16, 18, 20, 22, 24, 26, 28, 30 of the massage device 6 or between the components 16, 18, 20, 22, 24, 26, 28, 30 of the massage device 6 and ground 64. In summary, either the electromagnetic field 60 is created only between components 16, 18, 20, 22, 24, 26, 28, 30 of the massage device 6 or between the components 16, 18, 20, 22, 24, 26, 28, 30 of the massage device 6 and ground 64.

By means of the method 52, it can be recognized whether the user perceives the respective massage drive 16, 18, 20, 22, and thus whether it is currently in use. Unused massage drives 16, 18, 20, 22, i.e., those massage drives of which the assigned section is not occupied, are either switched off or operated at an acoustically advantageous operating point. In addition, the massage drives 16, 18, 20, 22 and the electrical lines 24, 26, 28, 30 can determine a detailed seat occupancy, and additional components for detecting the seat occupancy are not required. If the electromagnetic field 60 is created only between the components 16, 18, 20, 22, 24, 26, 28, 30 of the massage device 6, a special adjustment to other components of the seat 4 is not necessary, so that the assembly and design of the massage device 6 is simplified and is largely independent on the seat structure and in particular the support structure 44. As long as the electromagnetic field 60 is created between each component 16, 18, 20, 22, 24, 26, 28, 30 of the massage device 6 and ground 64, each of the components 16, 18, 20, 22, 24, 26, 28, 30 can be individually measured, resulting in a comparatively detailed seat occupancy detection.

The invention is not limited to the above-described embodiments. Rather, other variants of the invention can be derived therefrom by the person skilled in the art without departing from the scope of the invention. In particular, all individual features which are further described in association with the individual embodiments can also be combined in other ways without departing from the scope of the invention.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for operating a massage device of a seat of a motor vehicle having a massage drive with an unbalance that is driven via an electric motor and an electrical line for operating the massage drive, the method comprising:
detecting a change in capacitance, via a component of the massage device, due to a change in occupancy of at least one section of the seat; and
adjusting the energization of the electric motor based on the change in capacitance.

2. The method according to claim 1, wherein the capacitance is detected following a user input.

3. The method according to claim 1, wherein energization is increased if the detected capacitance corresponds to an occupancy of the section of the seat.

4. The method according to claim 1, wherein the capacitance between the component and a ground is calculated.

5. The method according to claim 1, wherein the capacitance between the component and a second massage drive and/or a second electrical line is calculated.

6. The method according to claim 1, wherein a housing of the massage drive or a housing of the electric motor is the component.

7. The method according to claim 1, wherein the electrical line is used as the component.

8. A massage device of a seat of a motor vehicle, the massage device comprising:
a massage drive that has an unbalance that is driven by an electric motor; and
an electrical line for operating the masage drive,
wherein the massage drive and/or the electrical line is assigned to a section, and which is operated according to the method according to claim 1.

9. The massage device according to claim 8, further comprising a third massage drive and/or a third electrical line, which are assigned to a second section.

10. A vehicle seat of a motor vehicle, in particular a driver's seat, comprising a massage device according to claim 8.

11. A system comprising a component of a massage device of a seat, in particular of a motor vehicle, as a capacitive sensor electrode for detecting the occupancy of at least one section of the seat, said massage device having a massage drive with an unbalance that is driven by an electric motor and an electrical line for operating the massage drive.
